(19) United States
(12) Patent Application Publication
(10) Pub. No.: US 2012/0074595 A1
(43) Pub. Date: Mar. 29, 2012

(54) SEMICONDUCTOR PACKAGE

(75) Inventors: JeongOh Ha, Hwaseong-si (KR); Heungkyu Kwon, Seongnam-si (KR); YunSeok Choi, Hwaseong Si (KR); Jong-Won Lee, Seoul (KR)

(73) Assignee: SAMSUNG ELECTRONICS CO., LTD., Suwon-si (KR)

(21) Appl. No.: 13/191,843

(22) Filed: Jul. 27, 2011

(30) Foreign Application Priority Data
Sep. 28, 2010 (KR) 10-2010-0093869

(51) Int. Cl. H01L 23/522

(52) U.S. Cl. 257/777; 257/E23.142

(57) ABSTRACT

A semiconductor package includes a first substrate on which a first semiconductor chip is mounted, a second substrate spaced apart from the first substrate and on which a second semiconductor chip is mounted, first pads disposed on the first substrate, second pads disposed on the second substrate to be opposite to the first pads, and connection patterns electrically connecting the opposite first and second pads to each other, respectively. The first pads are disposed asymmetrically with respect to the central axis of the first substrate.

### CROSS-REFERENCE TO RELATED APPLICATIONS

This US non-provisional patent application claims priority under 35 USC §119 to Korean Patent Application No. 10-2010-0093869, filed in the Korean Intellectual Property Office on Sep. 28, 2010, the entirety of which is hereby incorporated by reference.

### BACKGROUND OF THE INVENTION

The inventive concept described herein generally relates to semiconductor packages and, more particularly, to a multi-stack semiconductor package.

In a multi-stack semiconductor package, a plurality of semiconductor chips is mounted on a printed circuit board (PCB). The quantity of a plurality of conductive pads connecting the PCB to the semiconductor chips increases with an increase in the quantity of semiconductor chips mounted on the PCB. As a result, a fine pitch is applied to a space between the pads. Additionally, bonding wires connecting semiconductor chips with pads increase in length. As a result, electrical characteristics of the bonding wires may be degraded.

### SUMMARY OF THE INVENTION

According to one aspect, the inventive concept is directed to a semiconductor package. The semiconductor package includes: a first substrate; a first semiconductor chip mounted on the first substrate; a second substrate spaced apart from the first substrate; a second semiconductor chip mounted on the second substrate; first pads disposed on the first substrate; second pads disposed on the second substrate to be opposite to the first pads; and connection patterns electrically connecting the opposite first and second pads to each other, respectively. The first pads are disposed asymmetrically with respect to the central axis of the first substrate.

In some exemplary embodiments, first pads transmitting and receiving the same signal are collectively disposed in one region of the first substrate.

In some exemplary embodiments, one of the first pads transmitting and receiving the same signal deviates from the one region, and the semiconductor package further comprises a redistribution pad electrically connected to the one first pad and disposed in the one region.

In some exemplary embodiments, the semiconductor package further comprises an integrated first pad into which at least two of the first pads transmitting and receiving the same signal are integrated.

In some exemplary embodiments, the integrated first pad is greater in size than each of the first pads.

In some exemplary embodiments, the central axis of the first semiconductor chip deviates from the central axis of the first substrate.

In some exemplary embodiments, the central axis of the second semiconductor chip deviates from the central axis of the second substrate.

In some exemplary embodiments, the second pads are asymmetrical with respect to the central axis of the second substrate.

According to another aspect, the inventive concept is directed to a semiconductor package. The semiconductor package includes: a substrate; a semiconductor chip mounted on the substrate; and a plurality of connection patterns disposed on a first surface of the substrate, the connection patterns being disposed asymmetrically with respect to the central axis of the substrate.

In some exemplary embodiments, the semiconductor chip deviates from the central axis of the substrate.

In some exemplary embodiments, the semiconductor package further comprises a plurality of pads formed on the substrate to electrically connect the semiconductor chip to the connection patterns.

In some exemplary embodiments, pads transmitting and receiving the same signal are collectively disposed in one region of the substrate, and connection patterns connected to the pads are also collectively disposed in the one region of the substrate.

In some exemplary embodiments, the semiconductor package further comprises: an integrated pad into which at least two pads transmitting and receiving the same signal are integrated; and an integrated connection pattern electrically connected to the integrated pad.

In some exemplary embodiments, the integrated connection pattern has a greater size than each of the connection patterns.

According to another aspect, the inventive concept is directed to a semiconductor package. The semiconductor package includes: a first substrate; a first semiconductor chip mounted on the first substrate; a second substrate spaced apart from the first substrate; a second semiconductor chip mounted on the second substrate; first pads disposed on the first substrate; second pads disposed on the second substrate to be opposite to the first pads; and connection patterns electrically connecting the opposite first and second pads to each other, respectively. The first pads are disposed asymmetrically with respect to the central axis of the first substrate. First pads transmitting and receiving the same signal are collectively disposed in one region of the first substrate.

In some exemplary embodiments, the semiconductor package is the package of a semiconductor memory used with a memory card.

In some exemplary embodiments, the semiconductor package is the package of a semiconductor memory used in an information processing system.

In some exemplary embodiments, the central axis of the first semiconductor chip deviates from the central axis of the first substrate.

In some exemplary embodiments, the central axis of the second semiconductor chip deviates from the central axis of the second substrate.

In some exemplary embodiments, the second pads are asymmetrical with respect to the central axis of the second substrate.

### BRIEF DESCRIPTION OF THE DRAWINGS

The foregoing and other features and advantages of the inventive concept will be apparent from the detailed description of preferred embodiments of the inventive concept contained herein, as illustrated in the accompanying drawings, in which like reference characters refer to the same parts or elements throughout the different views. The drawings are not necessarily to scale, emphasis instead being placed upon illustrating the principles of the inventive concept. In the drawings, the thickness of layers and regions may be exaggerated for clarity.

FIG. 1A is a schematic top plan view of a semiconductor package according to an exemplary embodiment of the inventive concept.

FIG. 1B is a schematic cross-sectional view taken along the line I-I′ in FIG. 1A.

FIG. 1C is a schematic top plan view of a first pad of the semiconductor package shown in FIG. 1B.

FIG. 2 is a schematic top plan view of a semiconductor package according to another exemplary embodiment of the inventive concept.

FIG. 3A is a schematic top plan view of a semiconductor package according to another exemplary embodiment of the inventive concept.

FIG. 3B is a schematic cross-sectional view taken along the line III-III′ in FIG. 3A.

FIG. 4A is a schematic block diagram of a memory card provided with a semiconductor package according to an exemplary embodiment of the inventive concept.

FIG. 4B is a schematic block diagram of an information processing system using a memory provided with a semiconductor package according to an exemplary embodiment of the inventive concept.

### DETAILED DESCRIPTION

The advantages and features of the inventive concept will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to describe examples of the inventive concept and to let those skilled in the art understand the nature of the inventive concept.

In the specification, the dimensions of layers and regions may be exaggerated for clarity of illustration. It will also be understood that when an element such as a layer or substrate is referred to as being “on” another element, e.g., layer or substrate, it can be directly on the other element, e.g., layer or substrate, or intervening elements, e.g., layers or substrates, may also be present.

Exemplary embodiments of the inventive concept will be described below with reference to cross-sectional views and/or top plan views, which are exemplary drawings of the invention. The exemplary drawings are schematic in nature and actual shapes of features illustrated in the drawings may deviate from the idealized schematic illustrations in the drawings, due to manufacturing techniques and/or tolerances. Accordingly, the exemplary embodiments of the invention are not limited to specific configurations shown in the drawings, and include modifications based on the method of manufacturing the semiconductor device. For example, an etched region shown at a right angle may be formed in a rounded shape or formed to have a predetermined curvature. Therefore, regions shown in the drawings have schematic characteristics. In addition, the shapes of the regions shown in the drawings exemplify specific shapes of regions in an element, and do not limit the invention. Though terms such as first, second, and third are used to describe various elements in various embodiments of the inventive concept, the elements are not limited to these terms. These terms are used only to distinguish one element from another element. An embodiment described and exemplified herein includes a complementary embodiment thereof.

It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

The inventive concept will now be described more fully hereinafter with reference to the accompanying drawings, in which preferred embodiments of the inventive concept are shown.

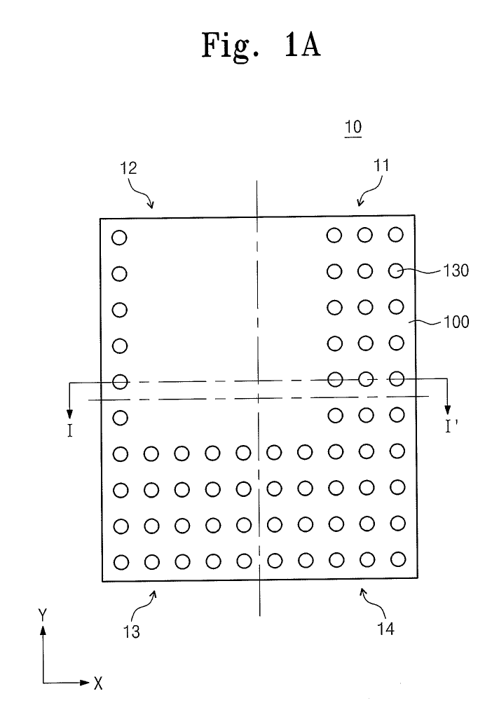

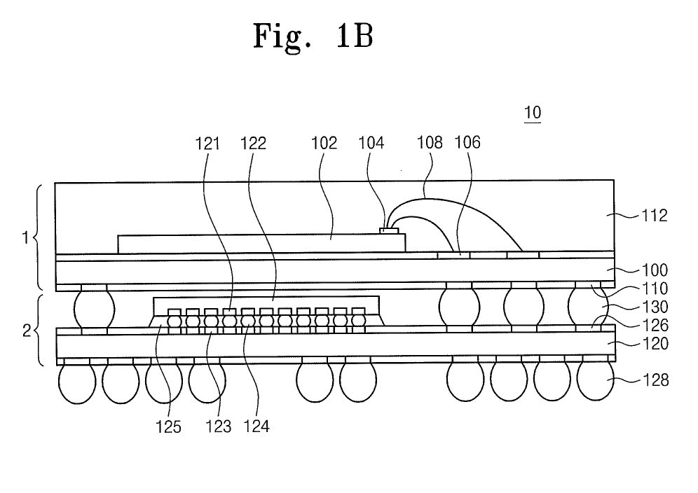

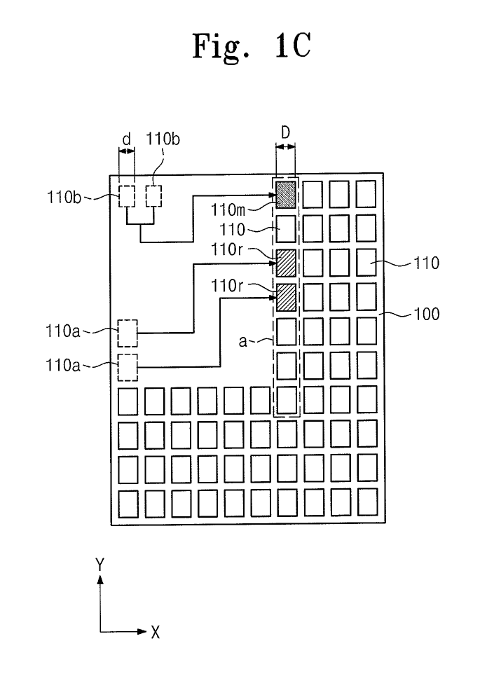

FIG. 1A is a schematic top plan view of a semiconductor package according to an exemplary embodiment of the inventive concept, and FIG. 1B is a schematic cross-sectional view taken along the line I-I′ in FIG. 1A. FIG. 1C is a schematic top plan view of a first pad of the semiconductor package 10 shown in FIG. 1B.

Referring to FIGS. 1A and 1B, the semiconductor package 10 according to some exemplary embodiments may include a first semiconductor chip package module 1 over a second semiconductor chip package 2, and connection patterns 130 electrically connecting the first semiconductor chip package module 1 with the second semiconductor chip package module 2.

As illustrated in FIG. 1B, the first semiconductor chip package 1 and the second semiconductor chip package 2 may be stacked vertically. Although this exemplary embodiment is described as including only two semiconductor chip package modules, in accordance with the inventive concept, at least two semiconductor chip package modules may be stacked vertically. It should be understood that the quantity of semiconductor chip package modules is not a limitation of the inventive concept.

According to one exemplary embodiment of the inventive concept, the semiconductor package may be a multi-stack package comprising a plurality of stacked semiconductor chips.

In some exemplary embodiments, the first semiconductor chip package module 1 may include a first substrate 100, a first semiconductor chip 102, first pads 110, and a first encapsulant 112.

In some exemplary embodiments, the first substrate 100 may be a semiconductor substrate containing, for example, silicon or germanium. The first substrate 100 may have a first surface and a second surface, that is, one surface and another surface. The first semiconductor chip 102 may be mounted on the one surface of the first substrate 100, and the first pads 110 may be mounted on the other surface thereof.

In general, the first semiconductor chip 102 may be mounted at a location that deviates from the central axis of the first substrate 100, on one surface of the first substrate 100. According to some exemplary embodiments of the inventive concept, the first semiconductor chip 102 may be wire-bonded to the first substrate 100. More specifically, first chip pads 104 may be disposed on the first semiconductor chip 102 and first substrate pads 106 may be disposed on the first substrate 100. A bonding wire 108 may be connected between each of the first chip pads 104 and each of the first substrate pads 106, such that each of the first chip pads 104 and each of the first substrate pads 106 may electrically connect the first semiconductor chip 102 with the first substrate 100 through a bonding wire 108.

In general, the first pads 110 may be disposed at a location that deviates from the central axis of the first substrate 100, on the other surface of the first substrate 100. According to some exemplary embodiments of the inventive concept, the first pads 110 may be disposed asymmetrically with respect to the central axis of the first substrate 100.

Referring to FIG. 1C, among the first pads 110, first pads 110 that transmit and receive the same signal may be collectively disposed at one region. For example, first pads 110a indicated by dotted lines may move into and occupy a region “A” through redistribution when they transmit and receive substantially the same signal as the first pads 110 disposed at the region “A”. First pads 110r indicated by oblique lines may be the first pads 110a which move into the region “A” through the redistribution. The first pads 110a may not actually be physically existing pads which is indicated by dotted lines for clarity of description.

In general, a portion receiving the same signal is disposed at one region of the first semiconductor chip 102. The first pads 110 transmitting and receiving the signal may be collectively disposed adjacent to the one region of the first semiconductor chip 102. As a result, in accordance with exemplary embodiments of the inventive concept, a signal distance between the first semiconductor chip 102 and the first pads 110 may be reduced to prevent generation of noise therebetween.

According to another exemplary embodiment of the inventive concept, the first pads 110 may be an integrated first pad 110m into which at least two first pads 110 transmitting and receiving the same signal are integrated. In addition, in some exemplary embodiments, the integrated first pad 110m may have a dimension “D” that is substantially greater than a dimension “d” of non-integrated first pads 110b.

The quantity of first pads 110 may decrease with the use of the integrated first pad 110m. Electrical reliability of first pads 110 may be improved with the use of a greater integrated first pad 110m. In some exemplary embodiments, the first pads 110b are not actually physically existing pads, which is indicated by dotted lines for clarity of description.

Returning to FIG. 1B, in some exemplary embodiments, the first encapsulant 112 may be formed on the first substrate 100 while covering the first semiconductor chip 102. In addition, in some exemplary embodiments, the first encapsulant 112 may be formed while covering the bonding wire 108 electrically connecting the first semiconductor chip 102 with the first substrate 100.

The first encapsulant 112 may protect the first semiconductor chip 102 and the bonding wire 108 from the effects of an external impact and may electrically insulate the first semiconductor chip 102 and the bonding wire 108 from an external element. In some exemplary embodiments, the first encapsulant 112 may be made of, for example, epoxy resin.

In some exemplary embodiments, the second semiconductor chip package module 2 may include a second substrate 120, a second semiconductor chip 122, second pads 126, and second encapsulant 125.

In some particular exemplary embodiments, the second substrate 120 may be a substrate disposed at the lowest portion in a multi-stack package. In some exemplary embodiments, the second substrate 120 may be, for example, a printed circuit board (PCB).

The second substrate 120 may have a first surface and a second surface, that is, one surface and another surface. The second semiconductor chip 122 may be mounted on the one surface of the second substrate 120, and the second pads 126 may be disposed thereon. External terminals 128 may be electrically connected to the other surface of the second substrate 120. In some particular exemplary embodiments, the external terminals 128 may be, for example, solder balls.

The second semiconductor chip 122 may be mounted at a location that deviates from the central axis of the second substrate 120, on the one surface of the second substrate 120. According to some exemplary embodiments of the inventive concept, the second semiconductor chip 122 may be electrically connected to the second substrate 120 through solder balls 124. More specifically, second chip pads 121 may be disposed on the second semiconductor chip 122 and second substrate pads 123 may be disposed on the second substrate 120. The second semiconductor chip 122 may be spaced apart from the second substrate 120 such that the second chip pads 121 face the second substrate pads 123. Solder balls 124 may be disposed at the space between the second semiconductor chip 122 and the second substrate 120 to electrically connect the second chip pads 121 to the second substrate pads 123.

The second pads 126 may be disposed at a location that deviates from the central axis of the second substrate 120, on the one surface of the second substrate 120. According to some exemplary embodiments of the inventive concept, the second pads 126 may be disposed at a location corresponding to the first pads 110. The second pads 126 may be disposed asymmetrically with respect to the central axis of the second substrate 120.

In some exemplary embodiments, the second encapsulant 125 may be formed while filling the space between the second substrate 120 and the second semiconductor chip 122. Also, in some exemplary embodiments, the second encapsulant 125 may be formed while covering the solder balls 124 electrically connecting the second substrate 120 to the second semiconductor chip 122.

The second encapsulant 125 may electrically insulate the solder balls 124 from an external element. In some exemplary embodiments, the second encapsulant 125 may be made of, for example, epoxy resin.

In some exemplary embodiments, the connection patterns 130 may electrically connect the first semiconductor chip package module 1 to the second semiconductor chip package module 2. More specifically, in some exemplary embodiments, the first semiconductor chip package module 1 and the second semiconductor chip package module 2 may be spaced apart from each other. The first pads 110 of the first semiconductor chip package module 1 may be disposed to face the second pads 126 of the second semiconductor chip package module 2. The second pads 126 may be disposed at locations corresponding to the first pads 110. The connection patterns 130 may be disposed at the space between the first semiconductor chip package module 1 and the second semiconductor chip package module 2 to electrically connect the first pads 110 to the second pads 126. In some exemplary embodiments, the connection patterns 130 may be, for example, solder balls.

In various exemplary embodiments described in detail below, various arrangement structures for 64 connection patterns 130 will be described. In this case, since the connection patterns 130 are electrically connected to the first pads 110 and the second pads 126, the arrangement of the first pads 110 and the second pads 126 may be substantially identical to that of the connection patterns 130.

Referring to FIG. 1A, the first substrate 100 is divided into four regions or quadrants on the basis of the X-axis and the Y-axis penetrating the center of the first substrate 100. In a counter-clockwise direction from a right upper portion, a first quadrant 11, a second quadrant 12, a third quadrant 13, and a fourth quadrant 14 are defined. The term “column” as used below means a structure in which five connection patterns are spaced apart from each other and arranged in an X-axis or Y-axis direction. In addition, in some exemplary embodiments, 5×5, i.e., 25, connection patterns 130 may be arranged in one quadrant, as illustrated in the exemplary embodiment shown in FIG. 1A.

In the first quadrant 11 of the first substrate 100, three columns may be aligned in the Y-axis direction to dispose fifteen connection patterns 130 among sixty four connection patterns 130. The three columns may be disposed on the edge of the first substrate 100. In the second quadrant 12, one column may be aligned in the Y-axis direction to dispose five connection patterns 130. The one column may be disposed on the edge of the first substrate 100. In the third quadrant 13, four columns may be aligned in the X-axis direction and one connection pattern 130 may be disposed adjacent to the X-axis to dispose twenty one connection patterns 130. In the fourth quadrant 14, four columns may be aligned in the X-axis direction and three connection patterns 130 may be disposed adjacent to the X-axis to dispose twenty three connection patterns 130.

It should be noted that the configuration shown in FIG. 1A and the description of this embodiment is merely exemplary. According to the inventive concept, various configurations are possible. Furthermore, in accordance with the inventive concept, connection patterns arranged asymmetrically on the basis of the center axis of the first substrate 100 may be possibly provided as the connection patterns 130.

According to another exemplary embodiment of the inventive concept, the first substrate 100 or the second substrate 200 may be provided with a chip selection pad. Among a plurality of stacked semiconductor chips, any semiconductor chip may be selectively driven through the chip's selection pad.

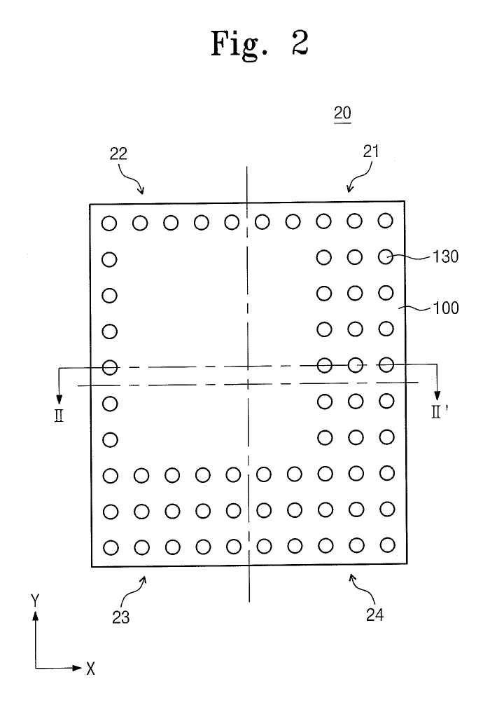

FIG. 2 is a schematic top plan view of a semiconductor package according to another exemplary embodiment of the inventive concept. A schematic cross-sectional view taken along the line II-IP in FIG. 2 is substantially identical to that of the semiconductor package shown in FIG. 1B and, therefore, is not duplicated herein. This exemplary embodiment will now be described with reference to FIG. 2 and FIG. 1B.

Referring to FIG. 2 and FIG. 1B, the semiconductor package 20 of these exemplary embodiments may include a first semiconductor chip package module 1, a second semiconductor chip package module 2, and connection patterns 130 electrically connecting the first semiconductor chip package module 1 to the second semiconductor chip package module 2. With the exception of the arrangement of connection patterns, the semiconductor package 20 is identical to that described in detail above with reference to FIGS. 1B and 1C. Therefore, detailed description will not be repeated.

In this exemplary embodiment, an arrangement structure for 64 connection patterns 130 will be described by way of an illustrative example. A first substrate 100 is divided into four regions or quadrants on the basis of X-axis and Y-axis penetrating the center of the first substrate 100. In a counter-clockwise direction from a right upper portion, a first quadrant 21, a second quadrant 22, a third quadrant 23, and a fourth quadrant 24 are defined. The term “column” as used below means a structure in which five connection patterns are spaced apart from each other and arranged in an X-axis or Y-axis direction. In addition, in some particular exemplary embodiments, 5×5, i.e., 25, connection patterns 130 may be arranged in one quadrant.

In the first quadrant 21 of the first substrate 100, three columns may be aligned in the Y-axis direction and two connection patterns 130 may be disposed adjacent to the Y-axis to dispose seventeen connection patterns 130. The three columns may be disposed on the edge of the first substrate 100. The two connection patterns 130 may be disposed on the edge of the first substrate 100 to be parallel with the X-axis. In the second quadrant 22, one column may be aligned in the Y-axis direction and four connection patterns 130 may be disposed adjacent to the Y-axis to dispose nine connection patterns 130. The one column may be disposed on the edge of the first substrate 100. The four connection patterns 130 may be disposed on the edge of the first substrate 100 to be parallel with the X-axis. In the third quadrant 23, three columns may be aligned in the X-axis direction and two connection patterns 130 may be disposed adjacent to the X-axis to dispose seventeen connection patterns 130. In the fourth quadrant 24, three columns may be aligned in the X-axis direction and six connection patterns 130 may be disposed adjacent to the X-axis to dispose twenty one connection patterns 130.

The above embodiment and the detailed description thereof is merely exemplary. In accordance with the inventive concept, connection patterns arranged asymmetrically on the basis of the center axis of the first substrate 100 are possibly provided as the connection patterns 130.

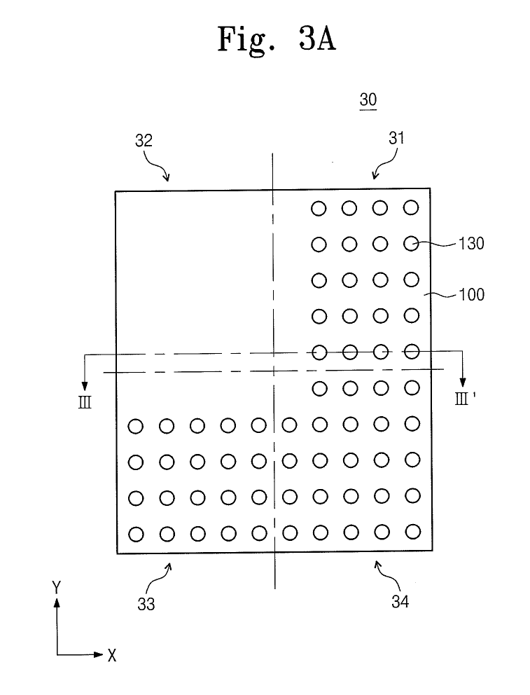

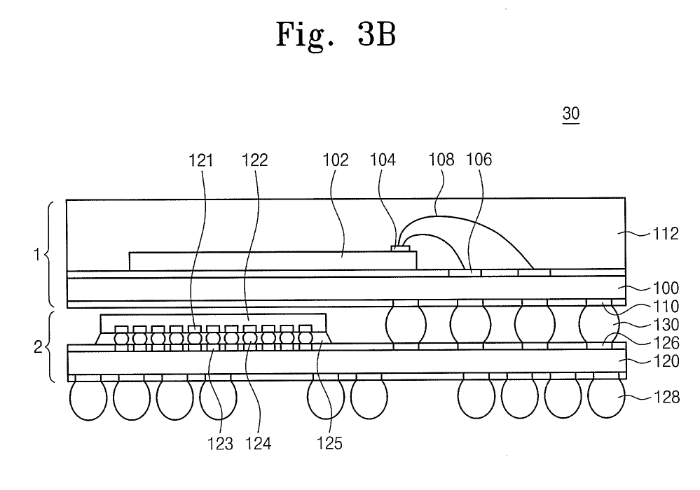

FIG. 3A is a schematic top plan view of a semiconductor package according to another exemplary embodiment of the inventive concept, and FIG. 3B is a schematic cross-sectional view taken along the line III-III′ in FIG. 3A.

Referring to FIGS. 3A and 3B, the semiconductor package 30 of these exemplary embodiments may include a first semiconductor chip package module 1, a second semiconductor chip package module 2, and connection patterns 130 electrically connecting the first semiconductor chip package module 1 to the second semiconductor chip package module 2.

The first semiconductor chip package module 1 may include a first substrate 100, a first semiconductor chip 102, first pads 110, and a first encapsulant 112. The first semiconductor chip package module 1 may further include first chip pads 104 disposed on the first semiconductor chip 102 and first substrate pads 106 disposed on the first substrate 100. The first chip pads 104 and the first substrate pads 106 may be electrically connected by a bonding wire 108. According to some exemplary embodiments of the inventive concept, first pads (110r in FIG. 1C) may be disposed in one region through redistribution. According to another exemplary embodiment of the inventive concept, the first pads 110 may include an integrated first pad (110m in FIG. 1C).

In some exemplary embodiments, the second semiconductor chip package module 2 may include a second substrate 120, a second semiconductor chip 122, second pads 126, and a second encapsulant 125. The second semiconductor chip package module 2 may further include second chip pads 121 disposed on the second semiconductor chip 122 and second substrate pads 123 disposed on the second substrate 120. In some exemplary embodiments, the second chip pads 121 and the second substrate pads 123 may be electrically connected by solder balls 124.

The connection patterns 130 may electrically connect the first semiconductor chip package module 1 to the second semiconductor chip package module 2.

In the exemplary embodiment described in detail below, an arrangement structure for 64 connection patterns 130 will be described. In some exemplary embodiments, the first substrate 100 is divided into four regions or quadrants on the basis of X-axis and Y-axis penetrating the center of the first substrate 100. In a counter-clockwise direction from a right upper portion, a first quadrant 31, a second quadrant 32, a third quadrant 33, and a fourth quadrant 34 are defined. The term “column” as used below means a structure in which five connection patterns are spaced apart from each other and arranged in an X-axis or Y-axis direction. In addition, in some exemplary embodiments, 5×5, i.e., 25, connection patterns 130 may be arranged in one quadrant.

In the first quadrant 31 of the first substrate 100, four columns may be aligned in the Y-axis direction to dispose twenty connection patterns 130 among sixty four connection patterns 130. The four columns may be disposed on the edge of the first substrate 100. In the second quadrant 32, no connection pattern 130 may be disposed. In the third quadrant 33, four columns may be aligned in the X-axis direction to dispose twenty connection patterns 130. The four columns may be disposed on the edge of the substrate 100. In the fourth quadrant 34, four columns may be aligned in the Y-axis direction and four connection patterns 130 may be disposed adjacent to the X-axis to dispose twenty four connection patterns 130. The four connection patterns 130 may be disposed to be parallel with the Y-axis.

Detailed description of like elements to those of FIGS. 1A to 1C, described in detail above, will not be repeated.

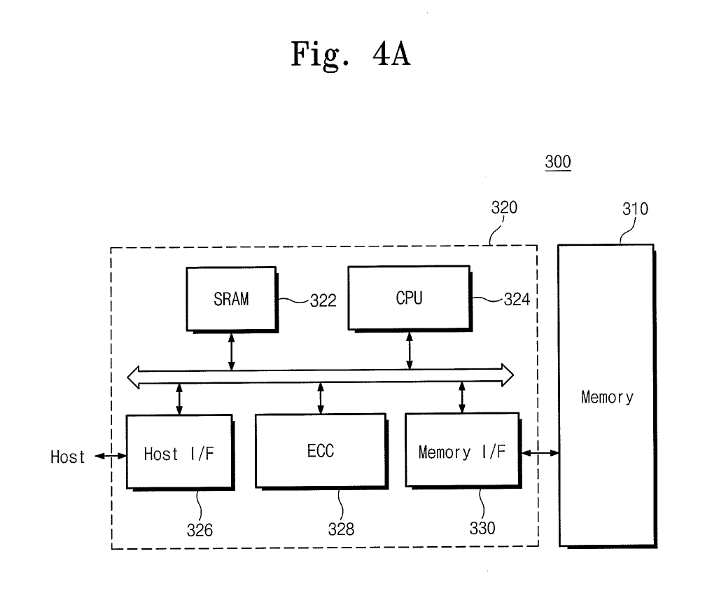

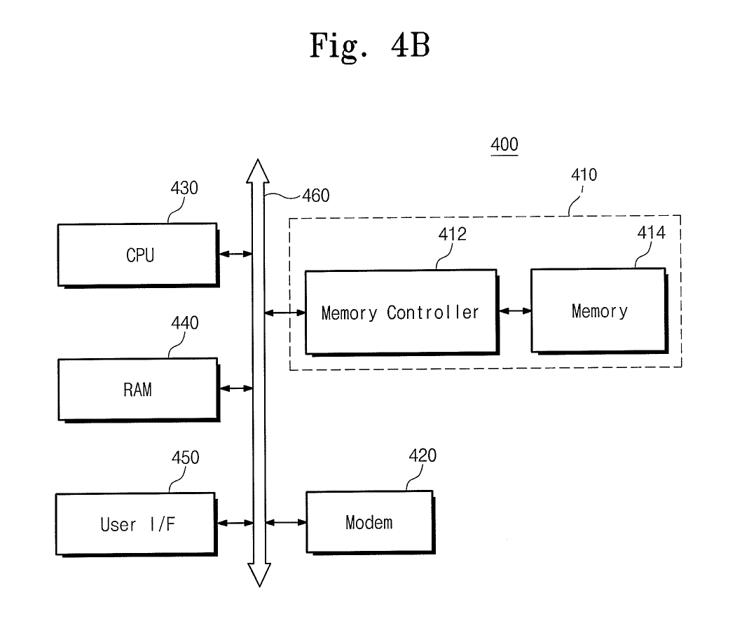

FIG. 4A is a schematic block diagram of a memory card 300 provided with a semiconductor package according to an exemplary embodiment of the inventive concept.

Referring to FIG. 4A, a semiconductor package according to any of the various exemplary embodiments of the inventive concept described above in detail may be applied to the memory card 300. In one example, the memory card 300 may include a memory controller 320 configured to control overall data exchange between a host and a semiconductor memory 310. An SRAM 322 may be used as a working memory of a central processing unit (CPU) 324. A host interface 326 may include a data exchange protocol of a host connected to the memory card 300. An error correction code (ECC) block 328 may detect and correct errors included in data read from the semiconductor memory 310. A memory interface 330 interfaces with the semiconductor memory 310. The CPU 324 performs the overall control operation for data exchange of the memory controller 320.

The semiconductor memory 310 applied to the memory card 300 may include a semiconductor package according to an exemplary embodiment of the inventive concept described herein in detail. According to the inventive concept, increasing a size of a connection pattern electrically connecting semiconductor package modules increases to enhance electrical reliability. Moreover, pads transmitting and receiving the same signal are collectively disposed to shorten the connection path.

FIG. 4B is a schematic block diagram of an information processing system 400 using a memory provided with a semiconductor package according to an exemplary embodiment of the inventive concept.

Referring to FIG. 4B, the information processing system 400 may include a memory system 410 including, for example, a resistance variable memory, according to an exemplary embodiment of the inventive concept. In some exemplary embodiments, the information processing system 400 may be or include, for example, a mobile device, a computer or the like. In one exemplary embodiment, the information processing system 400 may include the memory system 410 and a modem 420, a central processing unit (CPU) 430, a random access memory (RAM) 440, and a user interface 450, which are electrically connected to a system bus 460. Data processed by the CPU 430 or external input data may be stored in the memory system 410. The memory system 410 may include a memory 414 and a memory controller 412 and may be configured with substantially the same structure as the memory card 300 described above in detail with reference to FIG. 4A. In some exemplary embodiments, the information processing system 400 may be provided in the form of, for example, a memory card, a solid state disk (SSD), a camera image processor (CIS), and/or other application chipsets. In one exemplary embodiment, the memory system 410 may be configured with an SSD. In this case, the information processing system 400 can stably and reliably store high-capacity data in the memory system 410.

According to the foregoing embodiments of the inventive concept, pads transmitting and receiving the same signal are collectively arranged in one region to shorten a connection path with a semiconductor chip. In addition, there is provided an integrated pad into which at least two of the pads transmitting and receiving the same signal are integrated. The integrated pad allows the quantity of pads to be reduced. Thus, pads can increase in size to enhance electrical contact reliability.

While the inventive concept has been particularly shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A semiconductor package, comprising:
a first substrate;
a first semiconductor chip mounted on the first substrate;
a second substrate spaced apart from the first substrate;
a second semiconductor chip mounted on the second substrate;
first pads disposed on the first substrate;
second pads disposed on the second substrate to be opposite to the first pads; and
connection patterns electrically connecting the opposite first and second pads to each other, respectively,
wherein the first pads are disposed asymmetrically with respect to the central axis of the first substrate.

2. The semiconductor package of claim 1, wherein first pads transmitting and receiving the same signal are collectively disposed in one region of the first substrate.

3. The semiconductor package of claim 2, wherein one of the first pads transmitting and receiving the same signal deviates from the one region, and
the semiconductor package further comprises a redistribution pad electrically connected to the one first pad and disposed in the one region.

4. The semiconductor package of claim 2, further comprising an integrated first pad into which at least two of the first pads transmitting and receiving the same signal are integrated.

5. The semiconductor package of claim 4, wherein the integrated first pad is greater in size than each of the first pads.

6. The semiconductor package of claim 1, wherein the central axis of the first semiconductor chip deviates from the central axis of the first substrate.

7. The semiconductor package of claim 1, wherein the central axis of the second semiconductor chip deviates from the central axis of the second substrate.

8. The semiconductor package of claim 1, wherein the second pads are asymmetrical with respect to the central axis of the second substrate.

9. A semiconductor package, comprising:
a substrate;
a semiconductor chip mounted on the substrate; and
a plurality of connection patterns disposed on a first surface of the substrate, the connection patterns being disposed asymmetrically with respect to the central axis of the substrate.

10. The semiconductor package of claim 9, wherein the semiconductor chip deviates from the central axis of the substrate.

11. The semiconductor package of claim 9, further comprising a plurality of pads formed on the substrate to electrically connect the semiconductor chip to the connection patterns.

12. The semiconductor package of claim 11, wherein pads transmitting and receiving the same signal are collectively disposed in one region of the substrate, and connection patterns connected to the pads are also collectively disposed in the one region of the substrate.

13. The semiconductor package of claim 12, further comprising:
an integrated pad into which at least two pads transmitting and receiving the same signal are integrated; and
an integrated connection pattern electrically connected to the integrated pad.

14. The semiconductor package of claim 13, wherein the integrated connection pattern has a greater size than each of the connection patterns.

15. A semiconductor package, comprising:
a first substrate;
a first semiconductor chip mounted on the first substrate;
a second substrate spaced apart from the first substrate;
a second semiconductor chip mounted on the second substrate;
first pads disposed on the first substrate;
second pads disposed on the second substrate to be opposite to the first pads; and
connection patterns electrically connecting the opposite first and second pads to each other, respectively, wherein:
the first pads are disposed asymmetrically with respect to the central axis of the first substrate, and
first pads transmitting and receiving the same signal are collectively disposed in one region of the first substrate.

16. The semiconductor package of claim 15, wherein the semiconductor package is the package of a semiconductor memory used with a memory card.

17. The semiconductor package of claim 15, wherein the semiconductor package is the package of a semiconductor memory used in an information processing system.

18. The semiconductor package of claim 15, wherein the central axis of the first semiconductor chip deviates from the central axis of the first substrate.

19. The semiconductor package of claim 15, wherein the central axis of the second semiconductor chip deviates from the central axis of the second substrate.

20. The semiconductor package of claim 15, wherein the second pads are asymmetrical with respect to the central axis of the second substrate.
